(19) United States
(12) Patent Application Publication
(10) Pub. No.: US 2025/0006523 A1
(43) Pub. Date: Jan. 2, 2025

(54) APPARATUS AND METHODS FOR ADJUSTING PLATE TEMPERATURE

(71) Applicant: Applied Materials, Inc., Santa Clara, CA (US)

(72) Inventors: Zhepeng CONG, San Jose, CA (US); Alain DUBOUST, Sunnyvale, CA (US)

(21) Appl. No.: 18/629,481

(22) Filed: Apr. 8, 2024

Related U.S. Application Data
(60) Provisional application No. 63/510,536, filed on Jun. 27, 2023.

(51) Int. Cl. H01L 21/67; G05B 19/04

(52) U.S. Cl. CPC H01L 21/67248; G05B 19/041; H01L 21/67109; G05B 2219/25056

(57) ABSTRACT

A non-transitory computer readable medium to thermally adjust a chamber component is disclosed therein. The non-transitory computer readable medium includes instructions that when executed cause a plurality of operations to be conducted. The operations include sensing a first temperature of the chamber component within a semiconductor processing chamber, comparing the first temperature to a first set-point of the chamber component, and adjusting a purge gas flowrate of a purge gas supplied to a portion of the processing chamber. The plurality of operations include sensing a second temperature of a reflector component in the portion of the semiconductor processing chamber, comparing the second temperature of the reflector component to a second set-point of the reflector component, and initiating a reflector cooling operation within the reflector component when the second temperature exceeds the second set-point. The portion is at least partially physically isolated from a processing portion by a thermally transmissive window.

### CROSS-REFERENCE TO RELATED APPLICATIONS

This application claims benefit of U.S. Provisional Patent Application Ser. No. 63/510,536, filed Jun. 27, 2023, which is herein incorporated by reference.

### BACKGROUND OF THE DISCLOSURE

### Field of the Disclosure

The present disclosure relates to systems, apparatus, and methods for monitoring plate temperature for semiconductor manufacturing.

### Description of the Related Art

Semiconductor substrates are processed for a wide variety of applications, including the fabrication of integrated devices and microdevices. During processing, various parameters can affect the uniformity of material deposited on the substrate. For example, the temperature of the substrate and/or temperature(s) of processing chamber component(s) can affect deposition uniformity, processing rates, product yields, and product waste.

Additionally, control and adjusting of the chamber component temperature can be difficult, expensive, and/or inaccurate.

Therefore, a need exists for improved control of temperatures and related components that facilitate adjusting process parameters and monitoring temperatures.

### SUMMARY

The present disclosure relates to systems, apparatus, and methods for adjusting component (e.g., plate) temperature for semiconductor manufacturing.

In one or more embodiments, a non-transitory computer readable medium to thermally adjust a chamber component is provided. The non-transitory computer readable medium includes instructions that when executed cause a plurality of operations to be conducted. The plurality of operations include sensing a first temperature of the chamber component within a semiconductor processing chamber, comparing the first temperature to a first set-point of the chamber component, and adjusting a purge gas flowrate of a purge gas supplied to a portion of the semiconductor processing chamber. The plurality of operations include sensing a second temperature of a reflector component in the portion of the semiconductor processing chamber, comparing the second temperature of the reflector component to a second set-point of the reflector component, and initiating a reflector cooling operation within the reflector component when the second temperature exceeds the second set-point. The portion is at least partially physically isolated from a processing portion by a thermally transmissive window.

In one or more embodiments, a non-transitory computer readable medium to thermally adjust an isolation plate is provided. The non-transitory computer readable medium includes instructions that when executed cause a plurality of operations to be conducted. The plurality of operations include sensing a temperature of the isolation plate within a semiconductor processing chamber, comparing the sensed temperature to a set-point of the isolation plate, and adjusting a chilled purge gas flowrate of a chilled purge gas supplied to an isolated portion of an upper volume between a thermally transmissive window and the isolation plate. The plurality of operations include adjusting a purge gas flowrate of a purge gas supplied to a portion of the semiconductor processing chamber at least partially physically isolated from the isolated portion by the thermally transmissive window.

In one or more embodiments, a system for processing substrates and applicable for semiconductor manufacturing is provided. The system includes a chamber body including one or more sidewalls, a lid, a reflector component supported by the lid, one or more sensor devices disposed within the reflector component, and a window where the one or more sidewalls. The window and the lid at least partially define an internal volume. The system includes one or more heat sources configured to heat the internal volume, a substrate support disposed in the internal volume, an isolation plate disposed in the internal volume between the substrate support and the window, and a controller including instructions that, when executed, cause a plurality of operations to be conducted. The plurality of operations include sensing a first temperature of the isolation plate, comparing the first temperature to a first set-point of the isolation plate, and adjusting a purge gas flowrate of a purge gas supplied to a portion of the chamber body at least partially physically isolated from the internal volume by the window. The plurality of operations include sensing a second temperature of the reflector component in the portion of the chamber body, comparing the second temperature of the reflector component to a second set-point of the reflector component, and initiating a reflector cooling operation within the reflector component when the second temperature exceeds the second set-point.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 is a schematic side cross-sectional view of a processing chamber, according to one or more embodiments.

FIG. 2 is a schematic enlarged view of the processing chamber shown in FIG. 1, according to one or more embodiments.

FIG. 3 is a schematic partial view of a system including the processing chamber shown in FIG. 1, according to one or more embodiments.

FIG. 4A is a schematic graphical view of transmission profiles, according to one or more embodiments.

FIG. 4B is a schematic graphical view of transmission profiles, according to one or more embodiments.

FIG. 5 is a schematic block diagram view of a method of substrate processing, according to one or more embodiments.

FIG. 6A is a chart illustrating empirical data of the method of FIG. 5, according to one or more embodiments.

FIG. 6B is a chart illustrating the changes of the empirical data of the method of FIG. 5, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure relates to systems, apparatus, and methods for adjusting component (e.g., plate) temperature for semiconductor manufacturing.

The disclosure contemplates that terms such as “couples,” “coupling,” “couple,” and “coupled” may include but are not limited to welding, fusing, melting together, interference fitting, and/or fastening such as by using bolts, threaded connections, pins, and/or screws. The disclosure contemplates that terms such as “couples,” “coupling,” “couple,” and “coupled” may include but are not limited to integrally forming. The disclosure contemplates that terms such as “couples,” “coupling,” “couple,” and “coupled” may include but are not limited to direct coupling and/or indirect coupling, such as indirect coupling through components such as links, blocks, and/or frames.

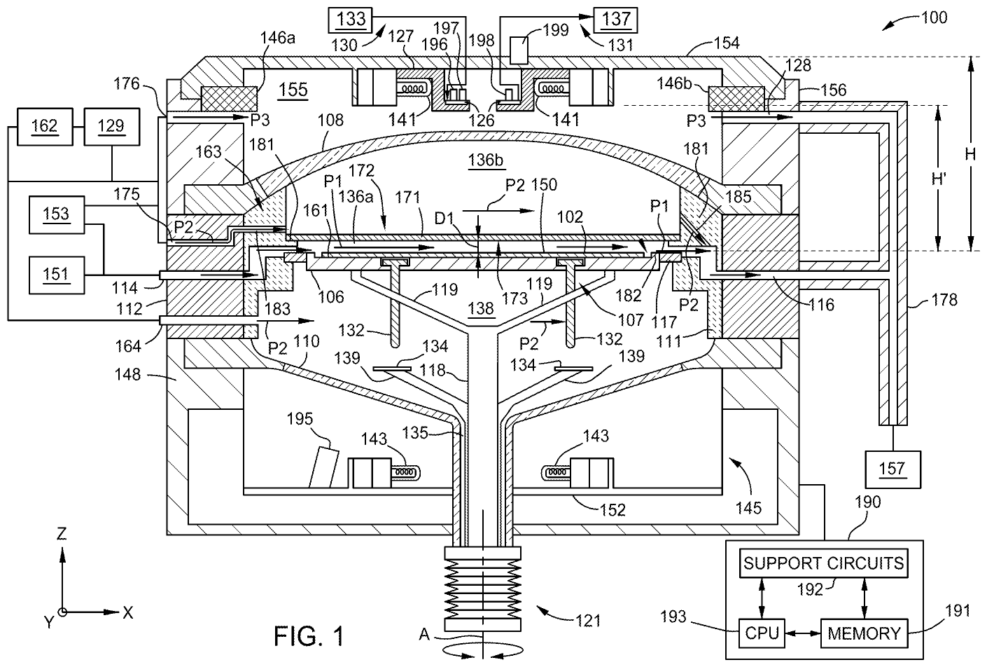

FIG. 1 is a schematic side cross-sectional view of a processing chamber 100, according to one or more embodiments. The processing chamber 100 is a deposition chamber. In one or more embodiments, the processing chamber 100 is an epitaxial deposition chamber. The processing chamber 100 is utilized to grow an epitaxial film on a substrate 102. The processing chamber 100 creates a cross-flow of precursors across a top surface 150 of the substrate 102. The processing chamber 100 is shown in a processing condition in FIG. 1.

The processing chamber 100 includes an upper body 156, a lower body 148 disposed below the upper body 156, and a flow module 112 disposed between the upper body 156 and the lower body 148. The upper body 156, the flow module 112, and the lower body 148 form a chamber body. The upper body 156 is fluidly connected to one or more purge gas inlets P (e.g., a plurality of purge gas inlets) and one or more gas exhaust outlets 128. The one or more purge gas inlets 176 are illustrated as being disposed on the opposite side of the one or more gas exhaust outlets 128 however it is contemplated the placement of the one or more purge gas inlets 176 and one or more gas exhaust outlets 128 may be strategically placed for ideal flow pathways. Purge gas flow within upper heat source module 155 is represented by P3, discussed below. Disposed within the chamber body is a substrate support 106, an upper window 108 (such as an upper dome), a lower window 110 (such as a lower dome), a plurality of upper heat sources 141, and a plurality of lower heat sources 143. In one or more embodiments, the upper heat sources 141 include upper lamps and the lower heat sources 143 include lower lamps. The present disclosure contemplates that other heat sources may be used (in addition to or in place of the lamps) for the various heat sources described herein. For example, resistive heaters, light emitting diodes (LEDs), and/or lasers may be used for the various heat sources described herein. Furthermore, the placement of the lamps in FIG. 1 is for visual representation and may be located in other strategic areas with an upper heat source module 155 and/or a lower heat sources module 145.

The substrate support 106 is disposed between the upper window 108 and the lower window 110. The substrate support 106 supports the substrate 102. In one or more embodiments, the substrate support 106 includes a susceptor. Other substrate supports (including, for example, a substrate carrier and/or one or more ring segment(s) that support one or more outer regions of the substrate 102) are contemplated by the present disclosure. The plurality of upper heat sources 141 are disposed between the upper window and a lid 154. The plurality of upper heat sources 141 form a portion of the upper heat source module 155. The lid 154 includes a support configured to suspend a reflector 127 that houses a plurality of sensor devices 196, 197, 198 disposed therein or thereon and configured to measures temperature(s) within the processing chamber 100. Sensor devices 196, 197, 198, 199 can be disposed on or within the lid 154, shown by height H (with respect to the top surface 150 of the substrate 102), however, by disposing the sensor devices 196, 197, 198 in the reflector 127 as shown by FIG. 1, the sensor devices 196, 197, 198 can be closer to the sensing targets and can facilitate an accurate measurement. In one or more embodiments, the sensor devices 196, 197, 198 are disposed in the reflector 127 to position the sensors at a height H′. The height H may be about 370 millimeters to about 410 millimeters, such as about 380 millimeters to about 400 millimeters, such as, for example 390 millimeters. The height H′ may be about 200 millimeters to about 240 millimeters, such as about 210 millimeters to about 230 millimeters, such as about 220 millimeters. By placing the sensor devices 196, 197, 198 within the reflector 127, the difference between height H and height H′ is about 150 millimeters to about 190 millimeters, such as about 160 millimeters to about 180 millimeters, such as about 170 millimeters. In one or more embodiments, a sensor device(s) 199 monitors the temperature of the reflector 127. The reflector 127 includes a cooling line 130 within the reflector 127 that facilitates a reflector cooling operation preventing the temperature of the plurality of sensor devices 196, 197, 198 from overheating. In one or more embodiments, the cooling line follows along a snake pattern within a channel 126 embedded in the surface of the reflector configured to surround the base of the plurality of sensor devices 196, 197, 198. In one or more embodiments, the channel 126 can be an open channel including a recessed groove having a bottom surface and two sidewalls. In one or more embodiments, the channel 126 can be machined into an inner surface of the reflector 127. In one or more embodiments, the channel 126 and can be an embedded enclosed channel. For example the channel 126 can be disposed within one or more hollow tubes embedded into the reflector 127. The reflector cooling operation can be a continuous, pulsed, and/or timed flow of a cooling fluid through cooling line(s) 130, 131, such as water, refrigerant, or other cooling medium (e.g., cooling flush). Furthermore, the cooling line(s) 130, 131 can help stabilize the reflector 127 temperature profile to be less than about 50 degrees Celsius, facilitating fewer thermal variations and less production waste from unstable processing. The cooling line inlet 130 and the cooling line outlet 131 are fluidly connected to a cooling source 133 and a disposal site 137. A lower sensor device 195 is configured to measure temperature(s) within the processing chamber 100. In one or more embodiments, each sensor device 195, 196, 197, 198, 199 is a pyrometer. In one or more embodiments, each sensor device 195, 196, 197, 198, 199 is an optical sensor device, such as an optical pyrometer. The present disclosure contemplates that sensors other than pyrometers may be used. Each sensor device 195, 196, 197, 198, 199 is a single-wavelength sensor device or a multi-wavelength (such as dual-wavelength) sensor device. The lower sensor device 195 is disposed adjacent to the floor 152.

In one or more embodiments, the process chamber 100 includes any one, any two, or any three of the five illustrated sensor devices 195, 196, 197, 198, 199.

In one or more embodiments, the process chamber 100 includes one or more additional sensor devices, in addition to the sensor devices 195, 196, 197, 198. In one or more embodiments, the process chamber 100 may include sensor devices disposed at different locations and/or with different orientations than the illustrated sensor devices 195, 196, 197, 198, 199. For example, one or more of the sensor devices 195, 196, 197, 198, 199, may be disposed in or on the lid 154 and/or disposed in or on the reflector 127.

The plurality of lower heat sources 143 are disposed between the lower window 110 and a floor 152. The plurality of lower heat sources 143 form a portion of the lower heat source module 145. The upper window 108 is an upper dome and/or is formed of an energy transmissive (e.g., thermally transmissive) material, such as quartz. In one or more embodiments, upper window 108 at least partially physically separates an upper portion of the process chamber 100 (in which the upper heat source module 155 is disposed) from the isolated portion 136b of the upper volume 136. The lower window 110 is a lower dome and/or is formed of an energy transmissive (e.g., thermally transmissive) material, such as quartz.

An upper volume 136 and a purge volume 138 are formed between the upper window 108 and the lower window 110. The upper volume 136 and the purge volume 138 are part of an internal volume defined at least partially by the upper window 108, the lower window 110, and one or more liners 111, 163.

The internal volume has the substrate support 106 disposed therein. The substrate support 106 includes a top surface on which the substrate 102 is disposed. The substrate support 106 is attached to a shaft 118. In one or more embodiments, the substrate support 106 is connected to the shaft 118 through one or more arms 119 connected to the shaft 118. The shaft 118 is connected to a motion assembly 121. The motion assembly 121 includes one or more actuators and/or adjustment devices that provide movement and/or adjustment for the shaft 118 and/or the substrate support 106 within the upper volume 136.

The substrate support 106 may include lift pin holes 107 disposed therein. The lift pin holes 107 are each sized to accommodate a lift pin 132 for lifting of the substrate 102 from the substrate support 106 before or after a deposition process is performed. The lift pins 132 may rest on lift pin stops 134 when the substrate support 106 is lowered from a process position to a transfer position. The lift pin stops 134 can include a plurality of arms 139 that attach to a shaft 135.

The flow module 112 includes one or more gas inlets 114 (e.g., a plurality of gas inlets), one or more purge gas inlets 164 and one or more gas exhaust outlets 116. The one or more gas inlets 114 and the one or more purge gas inlets 164 are disposed on the opposite side of the flow module 112 from the one or more gas exhaust outlets 116. A pre-heat ring 117 is disposed below the one or more gas inlets 114 and the one or more gas exhaust outlets 116. The pre-heat ring 117 is disposed above the one or more purge gas inlets 164. The one or more liners 111, 163 are disposed on an inner surface of the flow module 112 and protects the flow module 112 from reactive gases used during deposition operations and/or cleaning operations. The gas inlet(s) 114 and the purge gas inlet(s) 164 are each positioned to flow a respective one or more process gases P1 and one or more purge gases P2 parallel to the top surface 150 of a substrate 102 disposed within the upper volume 136. The gas inlet(s) 114 are fluidly connected to one or more process gas sources 151 and one or more cleaning gas sources 153. The purge gas inlet(s) 164 are fluidly connected to one or more purge gas sources 162. The one or more gas exhaust outlets 116 are fluidly connected to an exhaust pump 157. The one or more process gases P1 supplied using the one or more process gas sources 151 can include one or more reactive gases (such as one or more of silicon (Si), phosphorus (P), and/or germanium (Ge)) and/or one or more carrier gases (such as one or more of nitrogen (N₂) and/or hydrogen (H₂)). The one or more purge gases P2, P3, can be supplied using the one or more purge gas sources 162 can include one or more inert gases (such as one or more of argon (Ar), helium (He), air, and/or nitrogen (N₂)). In one or more embodiments, the air used from in one or more purge gas sources 162 can include dry air, saturated air, or some saturation between dry air and saturated air, such as, for example, ambient air or room air. Furthermore, the temperature(s) of the one or more purge gas sources 162 and/or the one or more purge gases P2 and/or P3 can be reduced by directing the one or more purge gases P2 and/or P3, towards the one or more chillers 129 to provide a purge of excess heat within the upper portion 136b or the upper heat source module 155. In one or more embodiments, the one or more purge gases P2 and/or P3 may be supplied by a variable speed blower (“VSB”). The VSB can be used as one or more of the one or more purge gas sources 162. One or more cleaning gases supplied using the one or more cleaning gas sources 153 can include one or more of hydrogen (H) and/or chlorine (Cl). In one or more embodiments, the one or more process gases P1 include silicon phosphide (SiP) and/or phosphine (PH₃), and the one or more cleaning gases include hydrochloric acid (HCl).

The one or more gas exhaust outlets 116, 128 are further connected to or include an exhaust system 178. The exhaust system 178 fluidly connects the one or more gas exhaust outlets 116, 128 and the exhaust pump 157. The exhaust system 178 can assist in the controlled deposition of a layer on the substrate 102. The exhaust system 178 is disposed on an opposite side of the processing chamber 100 relative to the flow module 112.

The processing chamber 100 includes a plate 171 (e.g., an isolation plate) having a first face 172 and a second face 173 opposing the first face 172. In one or more embodiments, the plate 171 is part of a flow guide structure. The second face 173 faces the substrate support 106. The processing chamber 100 includes the one or more liners 111, 163. An upper liner 163 includes an annular section 181 and one or more ledges 182 extending inwardly relative to the annular section 181. The one or more ledges 182 are configured to support one or more outer regions of the second face 173 of the plate 171. The upper liner 163 includes one or more inlet openings 183 and one or more outlet openings 185. In one or more embodiments, the plate 171 is in the shape of a disc, and the annular section 181 is in the shape of a ring. The plate 171 can be in the shape of a rectangle. The plate 171 divides the upper volume 136 between the substrate support 106 and the upper window 108 into a lower portion 136a and an upper portion 136b. The lower portion 136a is a processing portion and the upper portion 136b is an isolated portion. In one or more embodiments, the plate 171 is an isolation plate that at least partially physically isolates the isolated portion (e.g., the upper portion 136b) from the lower portion 136a.

The flow module 112 (which can be at least part of a sidewall of the processing chamber 100) includes the one or more gas inlets 114 in fluid communication with the lower portion 136a. The flow module 112 includes one or more second gas inlets 175 in fluid communication with the upper portion 136b. The one or more gas inlets 114 are in fluid communication with one or more flow gaps between the upper liner 163 and a lower liner 111. The one or more second gas inlets 175 are in fluid communication with the one or more inlet openings 183 of the upper liner 163.

During a deposition operation (e.g., an epitaxial growth operation), the one or more process gases P1 flow through the one or more gas inlets 114, through the one or more gaps, and into the lower portion 136a to flow over the substrate 102. During the deposition operation, one or more purge gases P2, flow through the one or more second gas inlets 175, through the one or more inlet openings 183 of the lower liner 111, and into the upper portion 136b. Also during the deposition operation, one or more purge gases P3, flow through the one or more purge gas inlets 176, and into the upper heat source module 155. The one or more purge gases P2, P3 can flow simultaneously with the flowing of the one or more process gases P1. The flowing of the one or more purge gases P3 through the upper heat source module 155 facilitates the upper heat source module 155 purging excess heat generated from the plurality of upper heat sources 141, or from the epitaxial growth operation, and thereby maintain a desired temperature profile for the upper heat source module 155, the upper window 108, and/or the plate 171. For example, there is an indirect temperature effect on the plate 171 described below. The flowing of the one or more purge gases P2 through the upper portion 136b facilitates reducing or preventing flow of the one or more process gases P1 into the upper portion 136b that would contaminate the upper portion 136b. The one or more purge gases P2 may be directed into the one or more chillers 129 to reduce the temperature of the one or more purge gases P2 to purge excess heat within the upper portion 136b thereby facilitating a reduced or flow prevention of the one or more process gases P1 into the upper portion 136b that would otherwise contaminate the upper portion 136b and also provide a cooling effect on the plate 171 described below.

The one or more process gases P1 are exhausted through gaps between the upper liner 163 and the lower liner 111, and through the one or more gas exhaust outlets 116. The one or more purge gases P2 are exhausted through the one or more outlet openings 185, through the same gaps between the upper liner 163 and the lower liner 111, and through the same one or more gas exhaust outlets 116 as the one or more process gases P1. The present disclosure contemplates that that one or more purge gases P2 can be separately exhausted through one or more second gas exhaust outlets that are separate from the one or more gas exhaust outlets 116.

The present disclosure also contemplates that the one or more purge gases P2 can be supplied to the purge volume 138 (through the one or more purge gas inlets 164) during the deposition operation, and exhausted from the purge volume 138.

During a cleaning operation, one or more cleaning gases flow through the one or more gas inlets 114, through the one or more gaps (between the upper liner 163 and the lower liner 111), and into the lower portion 136a. During the cleaning operation, one or more cleaning gases also simultaneously flow through the one or more second gas inlets 175, through the one or more inlet openings 183 of the upper liner 163, and into the upper portion 136b. The present disclosure contemplates that the one or more cleaning gases used to clean surfaces adjacent the upper portion 136b can be the same as or different than the one or more cleaning gases used to clean surfaces adjacent the lower portion 136a.

The processing chamber 100 facilitates separating the gases provided to the lower portion 136a from the gases provided to the upper portion 136b, which facilitates parameter adjustability. Additionally, one or more purge gases and one or more cleaning gases can be separately provided to the upper portion 136b to facilitate reduced contamination of the upper window 108 and/or the plate 171.

As shown, a controller 190 is in communication with the processing chamber 100 and is used to control processes and methods, such as the operations of the methods described herein.

The controller 190 is configured to receive data or input as sensor readings from a plurality of sensors. The sensors can include, for example: sensors that monitor growth of layer(s) on the substrate 102; sensors that monitor growth or residue on inner surfaces of chamber components of the processing chamber 100 (such as inner surfaces of the plate 171 and/or the one or more liners 111, 163); and/or sensors that monitor temperatures of the substrate 102, the substrate support 106, the plate 171, and/or the liners 111, 163. The controller 190 is equipped with or in communication with a system model of the processing chamber 100. The system model includes a heating model, a rotational position model, and/or a gas flow model. The system model is a program configured to estimate parameters (such as a gas flow rate, a gas pressure, a processing temperature, a rotational position of component(s), a heating profile, and/or a cleaning condition) within the processing chamber 100 throughout a deposition operation and/or a cleaning operation. The controller 190 is further configured to store readings and calculations. The readings and calculations include previous sensor readings, such as any previous sensor readings within the processing chamber 100. The readings and calculations further include the stored calculated values from after the sensor readings are measured by the controller 190 and run through the system model. Therefore, the controller 190 is configured to both retrieve stored readings and calculations as well as save readings and calculations for future use. Maintaining previous readings and calculations enables the controller 190 to adjust the system model over time to reflect a more accurate version of the processing chamber 100.

The controller 190 can monitor, estimate an optimized parameter, adjust a purge gas flow rate, adjust a chilled purge gas flow rate, initiate a reflector cooling operation, generate an alert on a display, halt a deposition operation, initiate a chamber downtime period, delay a subsequent iteration of the deposition operation, initiate a cleaning operation, detect a cleaning condition for the plate 171, halt the cleaning operation, adjust a heating power, and/or otherwise adjust the process recipe.

The controller 190 includes a central processing unit (CPU) 193 (e.g., a processor), a memory 191 containing instructions, and support circuits 192 for the CPU 193. The controller 190 controls various items directly, or via other computers and/or controllers. In one or more embodiments, the controller 190 is communicatively coupled to dedicated controllers, and the controller 190 functions as a central controller.

The controller 190 is of any form of a general-purpose computer processor that is used in an industrial setting for controlling various substrate processing chambers and equipment, and sub-processors thereon or therein. The memory 191, or non-transitory computer readable medium, is one or more of a readily available memory such as random access memory (RAM), dynamic random access memory (DRAM), static RAM (SRAM), and synchronous dynamic RAM (SDRAM (e.g., DDR1, DDR2, DDR3, DDR3L, LPDDR3, DDR4, LPDDR4, and the like)), read only memory (ROM), floppy disk, hard disk, flash drive, or any other form of digital storage, local or remote. The support circuits 192 of the controller 190 are coupled to the CPU 193 for supporting the CPU 193. The support circuits 192 include cache, power supplies, clock circuits, input/output circuitry and subsystems, and the like. Operational parameters (e.g., a temperature of the reflector 127, a temperature of the plate 171, a first set-point for the plate 171, a second set-point for the reflector 127, a purge gas flow rate, a chilled purge gas flow rate, a pressure for process gases P1, a processing temperature, a heating profile, a flow rate for process gases P1, a pressure for cleaning gases, a flow rate for cleaning gases, and/or a rotational position of a the substrate support 106) and operations are stored in the memory 191 as a software routine that is executed or invoked to turn the controller 190 into a specific purpose controller to control the operations of the various chambers/modules described herein. The controller 190 is configured to conduct any of the operations described herein. The instructions stored on the memory, when executed, cause one or more of operations of the method 500 (described below) to be conducted in relation to the processing chamber 100. The controller 190 and the processing chamber 100 are at least part of a system for processing substrates.

The various operations described herein (such as the operations of the method 500) can be conducted automatically using the controller 190, or can be conducted automatically or manually with certain operations conducted by a user.

In one or more embodiments, the controller 190 includes a mass storage device, an input control unit, and a display unit. The controller 190 monitors the temperature of the substrate 102, the temperature of the substrate support 106, the temperature of the plate 171, the process gas flow, and/or the purge gas flow. In one or more embodiments, the controller 190 includes multiple controllers 190, such that the stored readings and calculations and the system model are stored within a separate controller from the controller 190 which controls the operations of the processing chamber 100. In one or more embodiments, all of the system model and the stored readings and calculations are saved within the controller 190.

The controller 190 is configured to control the sensor devices 195, 196, 197, 198, 199, the deposition, the cleaning, the rotational position, the heating, and processing gas and purge gas flow paths prior to entry into and through the processing chamber 100, and additional chiller and heater controls, by providing an output to the controls for the heat sources, the gas flow, and the motion assembly 121. The controls include controls for the sensor devices 195, 196, 197, 198, the upper heat sources 141, the lower heat sources 143, the process gas source 151, the purge gas source 162, the chiller 129, the motion assembly 121, controls to orient gas flow paths, and the exhaust pump 157.

The controller 190 is configured to adjust the output to the controls based on the sensor readings, the system model, and the stored readings and calculations. The controller 190 includes embedded software and a compensation algorithm to calibrate measurements. The controller 190 can include one or more machine learning algorithms and/or artificial intelligence algorithms that estimate optimized parameters for the deposition operations and/or the cleaning operations (such as for adjusting a deposition operation (e.g. the process recipe), adjusting a purge gas flow rate, adjusting a chilled purge gas flow rate, initiating a reflector cooling operation, halting the deposition operation, initiating a chamber downtime period, delaying a subsequent iteration of the deposition operation, initiating a cleaning operation, halting the cleaning operation, adjusting a heating power, and/or adjusting the cleaning operation). The optimized parameter can include, for example, a pre-determined temperature on the plate 171 that initiates a purge gas cycle to remove excess heat generated from processing to adjust the temperature of the plate 171.

The one or more machine learning algorithms and/or artificial intelligence algorithms may implement, adjust and/or refine one or more algorithms, inputs, outputs or variables described above. Additionally or alternatively, the one or more machine learning algorithms and/or artificial intelligence algorithms may rank or prioritize certain aspects of adjustments of the process chamber 100, and/or the method 500 relative to other aspects of the process chamber 100, and/or the method 500. The one or more machine learning algorithms and/or artificial intelligence algorithms may account for other changes within the processing systems such as hardware replacement and/or degradation. In one or more embodiments, the one or more machine learning algorithms and/or artificial intelligence algorithms account for upstream or downstream changes that may occur in the processing system due to variable changes of the process chamber 100, and/or the method 500. For example, if variable “A” is adjusted to cause a change in aspect “B” of the process, and such an adjustment unintentionally causes a change in aspect “C” of the process, then the one or more machine learning algorithms and/or artificial intelligence algorithms may take such a change of aspect “C” into account. In such an embodiment, the one or more machine learning algorithms and/or artificial intelligence algorithms embody predictive aspects related to implementing the process chamber 100 and/or the method 500. The predictive aspects can be utilized to preemptively mitigate unintended changes within a processing system.

The one or more machine learning algorithms and/or artificial intelligence algorithms can use, for example, a regression model (such as a linear regression model) or a clustering technique to estimate optimized parameters. The algorithm can be unsupervised or supervised. The one or more machine learning algorithms and/or artificial intelligence algorithms can optimize, for example, a heating power applied to the heat sources 141, 143, a cleaning recipe, and/or a processing recipe. The one or more machine learning algorithms and/or artificial intelligence algorithms can optimize, for example, the temperature of the reflector 127, the temperature of the plate 171, the first set-point for the plate 171, the second set-point for the reflector 127, the purge gas flow rate, the chilled purge gas flow rate, a time for initiating a cleaning operation, and/or a time for initiating a deposition operation.

In one or more embodiments, the controller 190 automatically conducts the operations described herein without the use of one or more machine learning algorithms or artificial intelligence algorithms. In one or more embodiments, the controller 190 compares measurements to data in a look-up table and/or a library to determine if a purge gas flow rate and/or a chilled purge gas flow rate are to be conducted, and/or if a reflector cooling operation is to be conducted. The controller 190 can stored measurements as data in the look-up table and/or the library.

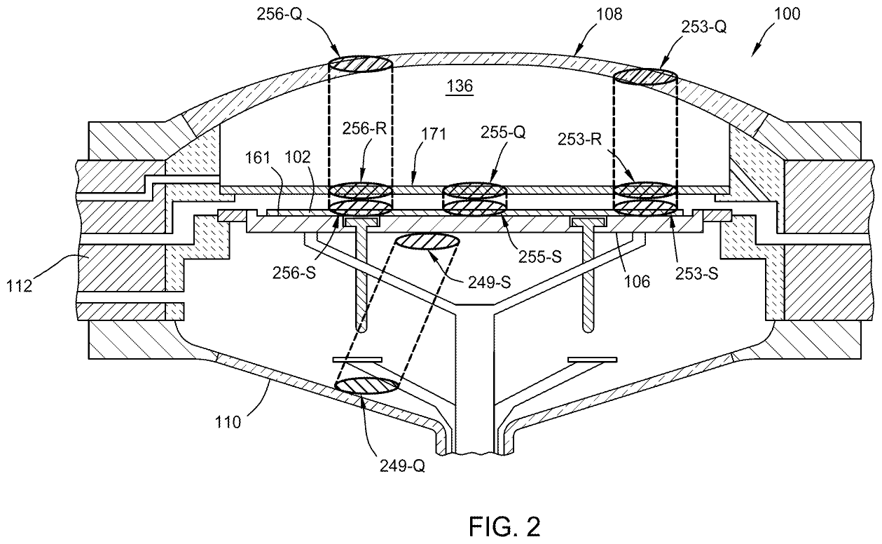

FIG. 2 is a schematic enlarged view of the processing chamber 100 shown in FIG. 1, according to one or more embodiments. The substrate support 106 has an upper surface 161 (e.g., a support surface) and a lower surface 169.

FIG. 2 also illustrates a plurality of temperature measurement sites 249-Q, 249-S, 253-Q, 253-R, 253-S, 255-Q, 255-S, 256-Q, 256-R, 256-S. For example, in one or more embodiments, the lower sensor device 195 (shown in FIG. 1) is configured to measure temperatures at site 249-Q (e.g., at a middle peripheral region of the lower window 110) and/or site 249-S (e.g., at a middle peripheral region of the lower surface 169 of the substrate support 106). In one or more embodiments, a first upper sensor device 196 (shown in FIG. 1) is configured to measure temperatures at site 255-Q (e.g., at a central region of the plate 171) and/or site 255-S (e.g., at a central region of the substrate 102 and/or a central region of the upper surface 161 of the substrate support 106). In one or more embodiments, a second upper sensor device 197 (shown in FIG. 1) is configured to measure temperatures at site 253-Q (e.g., at an outer peripheral region of the upper window 108), at site 253-R (e.g., at an outer peripheral region of the plate 171), and/or site 253-S (e.g., at an outer peripheral region of the substrate 102 and/or an outer peripheral region of the upper surface 161 of the substrate support 106). In one or more embodiments, a third upper sensor device 198 (shown in FIG. 1) is configured to measure temperatures at site 256-Q (e.g., at an outer peripheral region of the upper window 108), at site 256-R (e.g., at an outer peripheral region of the plate 171), and/or site 256-S (e.g., at an outer peripheral region of the substrate 102 and/or an outer peripheral region of the upper surface 161 of the substrate support 106). The sensor devices 195, 196, 197, 198 may be positioned and/or oriented differently than what is shown in FIG. 1 and FIG. 2, while still capable of measuring temperatures at a site on the plate 171, a site on one or more of the windows (e.g., upper window 108 and/or lower window 110), and/or a site on one of the surfaces of substrates support 106 (e.g., upper surface 161 and/or lower surface 169) and/or the substrate 102. Each of the sensor devices 195, 196, 197, 198 may be adapted to detect energy (e.g., radiation, such as light) at two or more (such as three or more) different wavelength ranges. For example, in one or more embodiments the two or three wavelength ranges of the upper sensor devices 196, 197, 198 are selected to be (1) a wavelength range at which the plate 171 is absorptive (e.g., about 2.48 microns to about 2.98 microns, such as about 2.7 microns), (2) a wavelength range at which the substrate support 106 and/or the substrate 102 is absorptive (e.g., about 3.17 microns to about 3.67 microns, such as about 3.4 microns), and (3) a wavelength range at which the upper window 108 and/or the lower window 110 is absorptive (e.g., about 4.75 microns to about 5.25 microns, such as about 5.0 microns).

The temperature measurements made by each of the sensor devices 195, 196, 197, 198 can be used to monitor component temperatures (such as plate 171 temperature) within the process chamber 100. For example, differences in temperature measurements may be utilized by the controller 190 to adjust the temperature of the plate 171, the upper window 108, and/or the lower window 110 by initiating and/or adjusting purge gas flow or chilled purge gas flow to the necessary area for temperature adjusting of the chamber component.

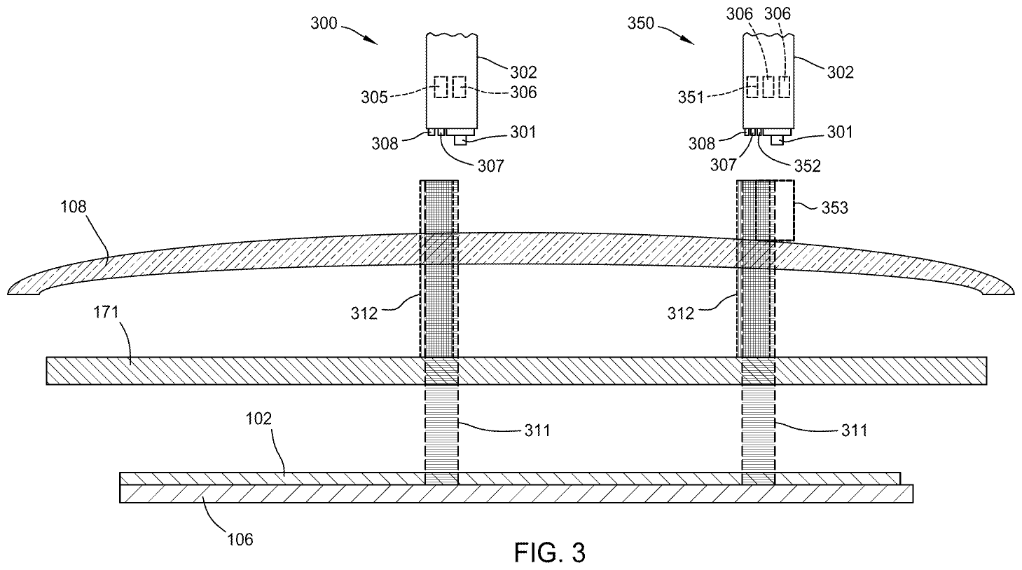

FIG. 3 is a schematic partial view of the system including the processing chamber 100 shown in FIG. 1, according to one or more embodiments. A sensor device 300 is disposed above the plate 171 and the upper window 108. The sensor device 300 can be used in place of one or more of the sensor devices 195, 196, 197, 198 shown in FIG. 1.

The sensor device 300 includes an eyepiece 301 mounted to a sensor housing 302. The sensor device 300 includes a first optical sensor 305 configured to detect energy having a first wavelength that is less than 4.0 microns, and a second optical sensor 306 configured to detect energy having a second wavelength that is less than the first wavelength. The optical sensor 305, 306 are disposed in the sensor housing 302. In one or more embodiments, the first wavelength is within a range of about 3.17 microns to about 3.67 microns, such as about 3.3 microns to about 3.5 microns. In one or more embodiments, the first wavelength is about 3.4 microns. In one or more embodiments, the second wavelength is within a range of about 2.48 microns to about 2.98 microns, such as about 2.6 microns to about 2.8 microns. In one or more embodiments, the second wavelength is about 2.7 microns.

The sensor device 300 includes a first light emitter 307 configured to emit a first beam 311 (e.g., light beam) toward a first area of the substrate support 106 (and/or the substrate 102). The sensor device 300 includes a second light emitter 308 configured to emit a second beam 312 (e.g., light beam) toward a second area of the plate 171. The second area of the second beam 312 overlaps with the first area of the first beam 311 by at least 80% of the first area. The second area overlaps with the first area, for example, along the vertical direction from the substrate support 106 and toward the plate 171. The eyepiece 301 is configured to collect reflected portions of the beams 311, 312 and the optical sensors 305, 306 are configured to measure the intensities of the reflected portions of the beams 311, 312 that have the respective first wavelength and second wavelength.

The upper window 108 includes a first quartz and the plate 171 includes a second quartz. The first quartz has a first hydroxyl concentration of less than 100 parts-per-million ppm). In one or more embodiments, the first hydroxyl concentration is 30 ppm or less, such as within a range of about 5 ppm to about 30 ppm. The second quartz has a second hydroxyl concentration of more than 750 parts-per-million (ppm). In one or more embodiments, the second hydroxyl concentration is 900 ppm or more. In one or more embodiments, the upper window 108 is formed of the first quartz and the plate 171 is formed of the second quartz. Other window(s), such as the lower window 110, can include the first quartz. For example, the lower window 110 can be formed of the first quartz. Using the first quartz and the second quartz facilitates accurately and efficiently measuring temperatures of the plate 171 and the substrate support 106 (and/or the substrate 102) during processing. As an example, the plate 171 having the higher second hydroxyl concentration facilitates accurately and efficiently measuring temperatures for the plate 171 using the second wavelength. The hydroxyl concentrations can be affected, for example, by the water content and/or contamination content in the respective first quartz or second quartz. The higher hydroxyl concentration of the second quartz involves a lower transmission of energy having the second wavelength. The higher hydroxyl concentration of the second quartz involves a higher transmission of energy having the first wavelength. In one or more embodiments, the second quartz is synthetic quartz, such as quartz formed using a soot process. In one or more embodiments, the first quartz is a fused quartz, such as electrically fused quartz. Other quartz materials (such as flame fused quartz) are contemplated for the first quartz and/or the second quartz.

Using the first quartz and the second quartz facilitates enhanced signal-to-noise ratios for the measurements. Using the first quartz, thermal non-uniformities affected by temperature gradients of the upper window 108 are reduced or eliminated. For example, gradients of the hydroxyl concentration across a diameter of the first quartz are reduced or eliminated to facilitate enhanced heating uniformity. As recited herein, the hydroxyl concentration refers to a parts-per-million (ppm) measurement of hydroxyl groups (e.g., groups including an oxygen atom covalently bonded to a hydrogen atom) in or on the respective quartz material. In one or more embodiments, the ppm measurement of the hydroxyl concentration is a measured concentration of hydroxyl groups relative to all other materials (such as contaminants and/or quartz) present on the respective quartz surfaces of the first quartz or the second quartz. In one or more embodiments, the measurement of the hydroxyl concentration is conducted by X-ray photoelectron spectroscopy (XPS) and provided in the unit of ppm. The present disclosure contemplates that other measurement techniques, such as glow discharge mass spectroscopy (GDMS), may be used to measure the ppm values of the hydroxyl concentration.

In one or more embodiments, the first quartz is transmissive for the first wavelength and the second wavelength discussed herein. In one or more embodiments, the second quartz is transmissive for the first wavelength and is absorptive for the second wavelength. In one or more embodiments, the material of the substrate support 106 is absorptive for the first wavelength. The first quartz facilitates reduced absorption and increased transmission (for the first wavelength and the second wavelength), and reduced power expenditures for heating. The first quartz can have a higher transmission (e.g., by over 5%) for infrared light relative to other materials, at a temperature of about 1000 degrees Celsius. The first quartz can facilitate for example, a power savings of over 5 KW per 100 KW expended. The first quartz facilitates increased heat ramp rates and increased throughput.

In one or more embodiments, the first quartz is transmissive for 75% or more (such as 80% or more) of energy (e.g., light) having the second wavelength. In one or more embodiments, the second quartz is transmissive for less than 5% (such as about 0%) of energy (e.g., light) having the second wavelength. The first quartz is fused quartz, such as electrically fused quartz. The second quartz is synthetic quartz, such as quartz formed using a soot process.

The sensor device 300 is shown as a multi-wavelength (e.g., dual-wavelength) sensor device. The present disclosure contemplates that the first optical sensor 305 can be disposed in a first sensor housing of a first sensor device, the first light emitter 307 can be mounted to the first sensor housing, the second optical sensor 306 can be disposed in a second sensor housing of a second sensor device, and the second light emitter 308 can be mounted to the second sensor housing. A first eyepiece can be mounted to the first sensor housing, and a second eyepiece can be mounted to the second sensor housing. The first sensor housing and the second sensor housing are positioned in relation to each other such that the first optical beam 311 overlaps (as described above) with the second optical beam 312 by at least 80%.

In addition to or in place of the sensor device 300, a sensor device 350 is disposed above the plate 171 and the upper window 108. The sensor device 350 can be used in place of one or more of the sensor devices 195, 196, 197, 198 shown in FIG. 1. The sensor device 350 includes a third optical sensor 351 configured to detect energy having a third wavelength that is greater than the first wavelength. The optical sensor 351 are disposed in the sensor housing 302. In one or more embodiments, the third wavelength is within a range of about 4.75 microns to about 5.25 microns, such as about 4.9 microns to about 5.1 microns. In one or more embodiments, the third wavelength is about 5.0 microns.

The sensor device 350 includes a third light emitter 352 configured to emit a third beam 353 (e.g., light beam) toward a third area of the upper window 108. The sensor device 350 includes the first light emitted 307 and the second light emitter 308. In one or more embodiments, the third area of the third beam 353 overlaps with the first area of the first beam 311 by at least 80% of the first area. The third area overlaps with the first area, for example, along the vertical direction from the substrate support 106 and toward the upper window 108. The eyepiece 301 is configured to collect reflected portions of the beams 311, 312, 353 and the optical sensors 305, 306, 351 are configured to measure the intensities of the reflected portions of the beams 311, 312, 353 that have the respective first wavelength, second wavelength, and third wavelength. Measuring the third beam 353 using the third wavelength can be used to determine a temperature profile for the upper window 108. The lower hydroxyl concentration of the third quartz involves a lower transmission of energy having the third wavelength. In one or more embodiments, the first quartz is absorptive for the third wavelength. In one or more embodiments, the first quartz is transmissive for less than 5% (such as about 0%) of energy (e.g., light) having the third wavelength.

The sensor device 350 is shown as a multi-wavelength (e.g., triple-wavelength) sensor device. The present disclosure contemplates that the first optical sensor 305 can be disposed in a first sensor housing of a first sensor device, the first light emitter 307 can be mounted to the first sensor housing, the second optical sensor 306 can be disposed in a second sensor housing of a second sensor device, the second light emitter 308 can be mounted to the second sensor housing, the third optical sensor 351 can be disposed in a third sensor housing of a third sensor device, the third light emitter 352 can be mounted to the third sensor housing. A first eyepiece can be mounted to the first sensor housing, a second eyepiece can be mounted to the second sensor housing, and a third eyepiece can be mounted to the third sensor housing. The first sensor housing the second sensor housing, and the third sensor housing are positioned in relation to each other such that the first optical beam 311 overlaps (as described above) with the second optical beam 312 by at least 80%, and the third optical beam 353 overlaps (as described above) with the first optical beam 311 by at least 80%.

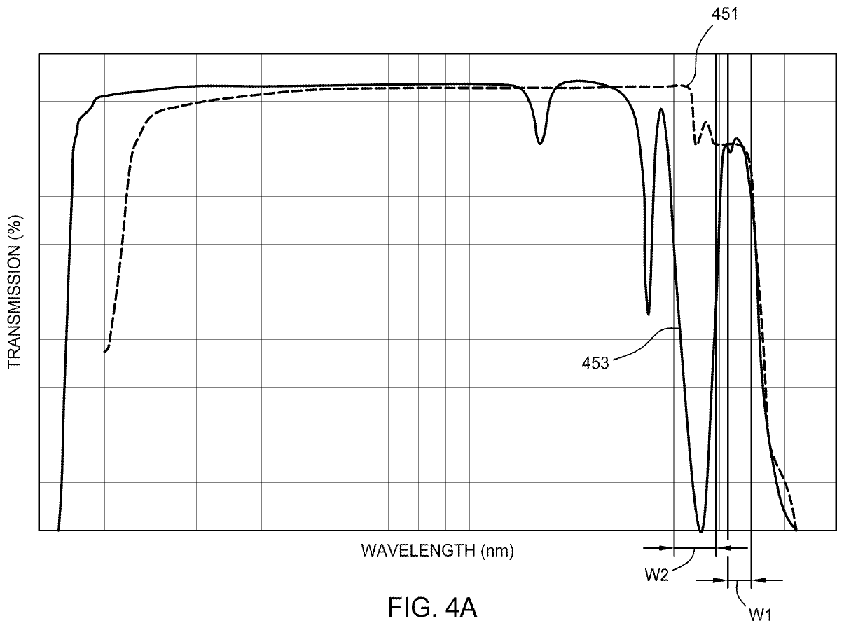

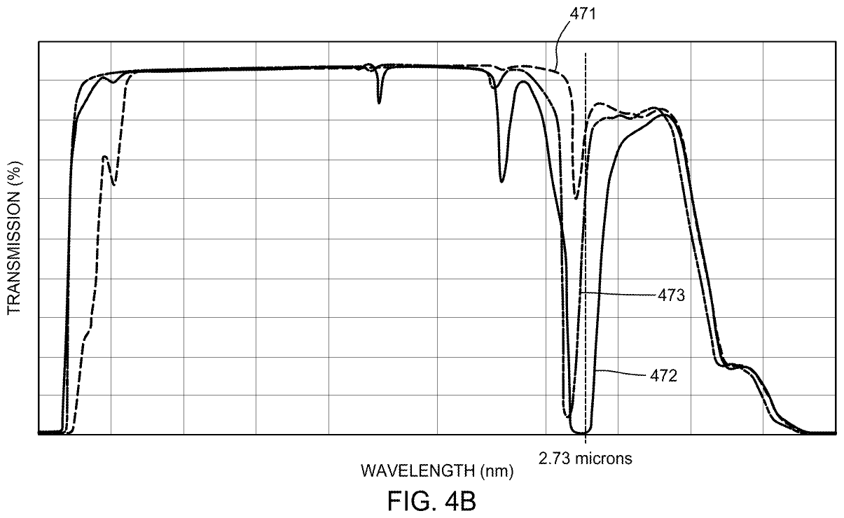

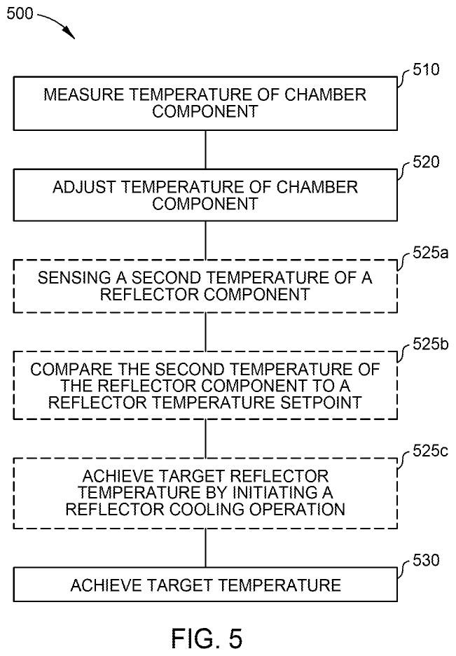

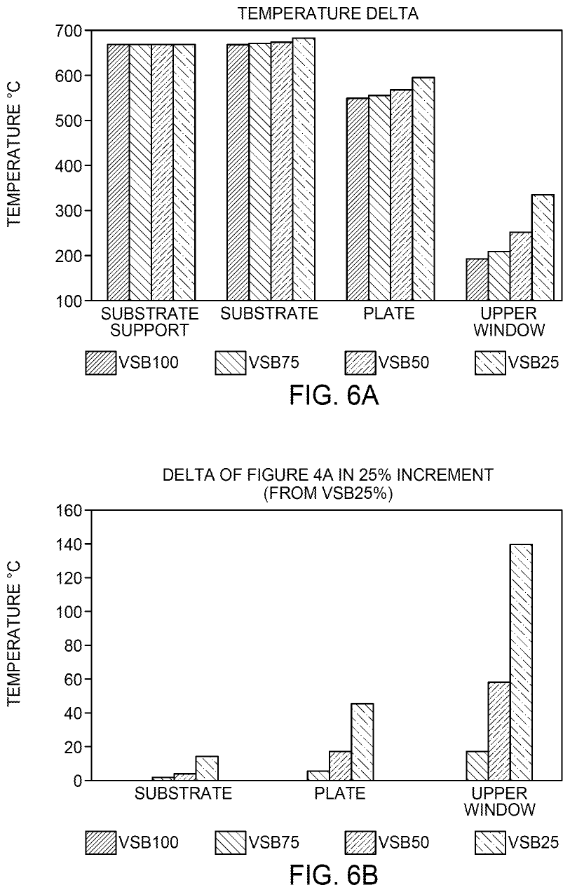

FIG. 4A is a schematic graphical view of transmission profiles 451-453, according to one or more embodiments. The transmission profiles 451-453 are shown across a plurality of wavelengths. Line 451 is an exemplary transmission profile of the upper window 108. Line 451 is an exemplary transmission profile of the upper window 108. Line 453 is an exemplary transmission profile of the plate 171. As shown at the first wavelength W1 (discussed above as, for example, a range), energy having the first wavelength W1 can transmit both through the upper window 108 and the plate 171 to reach the substrate 102 and/or the substrate support 106). At the first wavelength W1, the upper window 108 and the plate 171 both have a relatively high transmission (e.g., 80% or higher).

As shown at the second wavelength W2 (discussed above as, for example, a range), energy having the second wavelength W2 can transmit through the upper window 108 and be absorbed and/or reflected by the plate 171. At the second wavelength W1, the upper window 108 has a relatively high transmission (e.g., 80% or higher) and the plate 171 has a relatively low transmission (e.g., less than 80%, such as less than 50%, less than 20%, or less than 10%, for example 5% or less, such as about 0%).

FIG. 4B is a schematic graphical view of transmission profiles 471-473, according to one or more embodiments. The transmission profiles 471-473 are shown across a plurality of wavelengths. Line 471 is an exemplary transmission profile of the first quartz described above. Line 472 is an exemplary transmission profile of the second quartz described above. Line 473 is an exemplary transmission profile of a third quartz. As shown at a wavelength of about 2.73 microns (e.g., in the second wavelength range described above), the line 471 has a transmissivity of that is 75% or higher (such as 80% or higher). The line 472 has a transmissivity that is less than 5% (such as about 0%). The line 473 has a transmissivity that is within a range of 55% to 70%. The line 471 is for fused quartz that is formed using electrical fusion. The line 472 is a synthetic quartz formed using a soot process. The line 473 is a fused quartz formed using flame fusion.

As shown at the wavelength of about 2.73 microns, the first line 471 (e.g., for the upper window 108) has a relatively high transmission and the second line 473 (e.g., for the plate 171) has a relatively low transmission.

FIG. 5 is a diagram view of a temperature control method 500 that includes a plurality of operations to control the temperature of a chamber component (such as the plate 171 of FIG. 1), according to one or more embodiments. Operation 510 is a temperature sensing (e.g., monitoring) process. Operation 520 is method of adjusting the temperature of the chamber component. Operation 530 is a method of determining if a target temperature has been achieved. Discussions on FIG. 5 below will utilize reference numerals from FIG. 1.

As mentioned above, temperature monitoring and control of chamber components (such as the plate 171) is difficult as chamber components can be subjected to various temperature gradients from multiple heat or cooling sources. For example, an epitaxial growth deposition process may generate heat from the plurality of upper heat sources 141 within the upper heat source module 155 such that a base (such as a lamp base to which a lamp bulb is mounted) of each upper heat source 141 is heated to a base temperature that is 350 degrees Celsius or less. The present disclosure contemplates that the base temperature can be lower, such as lower than about 50 degrees Celsius. The heat can overheat the reflector 127 and housed devices. However, the temperature of the reflector 127, measureable by the optical device 199, can initiate the reflector 127 cooling cycle operation to maintain optical device integrity causing a cooled zone in the upper heat source module 155 to maintain the reflector 127 at a temperature below about 50 degrees Celsius. As discussed below, an increase in the temperature of the upper heat source module 155 may be performed by lessening an air purge provided from the one or more purge gas sources 162, such as a VSB. In one or more embodiments, as discussed below, cooling of the upper heat source module 155 may be from, for example, increasing an air purge provided from the one or more purge gas sources 162, such as a VSB. In one or more embodiments, as discussed below, a chilled purge gas is used to cool the upper heat source module 155.

These dynamic temperature gradients may affect chamber component temperature monitoring and control. For example, the heat from within the upper heat source module 155 radiates through the upper window 108 and affects the temperature of, for example, substrate support 106 and/or the substrate 102. As another example, the heat of the substrate support 106 and/or the substrate 102 can transfer (e.g., radiate) to the plate 171. The temperature of the plate 171 may affect (and/or may be affected by) the temperature gradient of the space between substrate support 106 and the plate 171 thereby affecting the epitaxial growth deposition on the substrate 102. By adjusting the temperature of the upper window 108 and/or the substrate support 106, the temperature of the plate 171 can be adjusted (e.g., indirectly). The temperature of the upper window 108 and/or the substrate support 106 can be adjusted across temperature ranges. Adjusting the temperature of the plate 171 facilitates deposition growth rates for the substrate 102 and/or center-to-edge deposition uniformity for the substrate 102. For example, adjusting a temperature gradient extending from the substrate support 106 and across the plate 171 facilitates enhancing center-to-edge deposition uniformity for the substrate 102. The present disclosure contemplates that the temperature of the plate 171 can be adjusted while substantially maintaining a temperature of the substrate support 106 across processing cycles.

Operation 510 is a temperature sensing process utilizing the sensor devices 300, 350, and/or 196, 197, 198, discussed above, to obtain an accurate measurement of the temperature of the chamber component (e.g., the plate 171). The temperature value obtained may be stored, compared to previously collected parameters, and/or initiate operation 520. In one or more embodiments, operation 510 includes comparing a first temperature of the chamber component to a first set-point of the chamber component.

Operation 520 is method of adjusting the temperature of the chamber component (e.g., the plate 171). Adjusting the temperature of the chamber component may be performed by methods such as incremental purging the upper heat source module 155 with air to remove excess heat generation, raising or lowering the heated substrate support 106, additional heater placements, and/or cooled purge gases in desired areas. For example, the temperature of the plate 171 can be indirectly adjusted.

The variable speed blower (“VSB”) provides an air flow path (represented as purge, P3, of FIG. 1) providing a back pressure of up to about 2 kilo Pascals (kPa) in the upper heat source module 155. It is to be understood that a reduction of back pressure will increase a cooling effect (and vice versa) and therefore, the distribution of air may be optimized for cooling other chamber components. For example, the VSB allows for incremental reductions in air flow (i.e., increased back pressure) to reduce the air throughput within the upper heat source module 155 while maintaining proper air throughput to, for example, the upper portion 136b and/or the purge volume 138. For example, the heat generated during an epitaxial growth operation achieves temperatures of the plate 171 of up to about 600 degrees Celsius with a VSB flowrate at 100 percent by indirectly heating the upper window 108. Similarly, in one or more embodiments the heat generated during an epitaxial growth operation achieves plate 171 temperatures of up to about 575 degrees Celsius with a VSB flowrate at 75 percent. In one or more embodiments the heat generated during an epitaxial growth operation achieves plate 171 temperatures of up to about 550 degrees Celsius with a VSB flowrate at 50 percent. In one or more embodiments, the heat generated during an epitaxial growth operation achieves plate 171 temperatures of up to about 545 degrees Celsius with a VSB flowrate at 25 percent. By incrementally reducing the flowrate of the VSB in 25 percent increments, it was discovered that the substrate 102 temperature varies by 15 degrees Celsius allowing for definitive adjusting or control of the plate 171 temperature within a 50 degrees Celsius range with reduced substrate 102 processing temperature variations. In one or more embodiments, the VSB may be reduced by increments smaller than 25 percent increments, such as about 10 percent increments, about 5 percent increments, or about 1 percent increments. Incrementally increasing the VSB flow rate can beneficially provide a cooling of the chamber component (e.g., plate 171) temperature. In other words, the heating of the upper heat source module 155 may be performed by incrementally reducing air flow and similarly, the cooling of the upper heat source module 155 may be performed by incrementally raising the reduced air flow.

In addition to incrementally purging the upper heat source module 155 as described above, the substrate support 106 can be adjusted to further affect the temperature radiation to the chamber component, (e.g., plate 171) using the process heated substrate support 106. In one or more embodiments, the substrate support 106 may include an embedded heater. To establish a benchmark for the incremental purging the upper heat source module 155, the substrate support 106 can be raised or lowered to achieve the same substrate support 106 temperature of about 675 degrees Celsius while simultaneously performing the incremental purging. Such an embodiment facilitates achieving a target temperature of the chamber component by utilizing both incremental air purging of the upper heat source module 155 and raising or lowering of the substrate support 106.

In one or more embodiments, an additional heater(s) 146a, 146b, may be disposed above the upper window 108 and within the upper heat source module 155 to further heat the upper heat source module 155 and the upper window up to about 750 degrees Celsius to about 800 degrees Celsius. In one or more embodiments, the additional heater(s) 146a, 146b each includes an electrode embedded in a silicon carbide (SiC) structure. In one or more embodiments, the heaters 146a, 146b are a unitary ring configured to radiate thermal energy in a downward direction to heat the upper window 108. The heaters 146a, 146b can be two independent heaters or can be integrated as a single heater, such as a single complete ring. In one or more embodiments, the additional heater(s) 146a, 146b disposed circumferentially about a sleeve section of the reflector 127. In one or more embodiments, the heater(s) 146a, 146b, may be a ceramic heater(s), such as a silicon carbide containing heater, and may have a variable temperature control to facilitate further adjusting of the chamber component (e.g., plate 171) temperature. The heater(s) 146a, 146b will raise the temperature of the upper heat source module 155, which indirectly heats the upper window 108, which indirectly heats the upper portion 136b, and which indirectly heats the plate 171 to a target temperature. Therefore, it is understood that expanding the window temperature control range will provide adjusting (e.g., indirect adjusting) of the chamber component (e.g., plate 171) temperature.

The chamber component (e.g., plate 171) temperature may be further lowered by selectively purging the upper portion 136b with a chilled purge gas. This may be performed simultaneously or after the VSB flowrate achieves full flow at 100 percent flowrate. The purge gas may be an inert gas or air supplied from the one or more purge gas sources 162. The one or more chillers 129 may be utilized to provide a lower temperature gas to the upper portion 136b in the flow path represented by P2 in FIG. 1. The cooling of the upper portion 136b cools the plate 171 through convective thermal transfer. It is to be understood that adjusting the plate 171 temperature using incremental air purging the upper heat source module 155, raising or lowering the substrate support 106, utilizing an additional heater within the upper heat source module 155, and/or using a chilled gas purge with the upper portion 136b may be used simultaneously, in combination, consecutively and/or in any order of operations to adjust the chamber component (e.g., plate 171) temperature.

Operation 525a, b, and c are optional method operations to achieve a target temperature of the reflector 127. The optional method operations may be performed by sensing a temperature of the reflector 127 in the upper heat source module 155 by the sensor device(s) 199 (i.e., operation 525a), comparing the second temperature of the reflector 127 to a second set-point (e.g. desired target reflector temperature) (i.e., operation 525b), and initiating a reflector 127 cooling operation within the reflector 127 when the second temperature exceeds the second set-point (operation 525c).

Operation 530 is a method of determining if the target temperature has been achieved. The measured temperature utilizing the sensor devices 300, 350, and/or 195, 196, 197, 198, 199, may be compared to the target temperature. If the desired temperature is not achieved, operations of the method 500 may be repeated until the desired plate 171 temperature is achieved. For example, the controller 190 may be programmed with a first set-point (e.g. “desired temperature”) for the temperature of the chamber component (e.g., the plate 171) and will compare the first set-point with the measured first temperature of operation 510. Any discrepancy will be calculated by the controller 190 and the controller 190 will initiate an adjustment of the chamber component temperature through any method described in operation 520. If the first set-point is not matched or exceeded, the method 500 is repeated.

FIG. 6A illustrates the temperatures empirically achieved by incremental reduction of the VSB flowrates to heat the plate 171, according to one or more embodiments. As shown, by adjusting the substrate support 106 to about 675 degrees Celsius and further reducing VSB flowrate across three increments from 100% to 25%, the plate 171 was able to achieve about 600 degrees Celsius.

FIG. 6B illustrates the change in temperature control ranges with the incremental air flows discussed above. As shown, with a substrate support 106 adjustment and four incremental air flows, the plate 171 temperature control range was within 50 degrees Celsius. The upper window 108 temperature control range was within 150 degrees Celsius and the substrate 102 temperature control range was within 15 degrees Celsius.

Benefits of the present disclosure include accurate, quick, efficient, and automatic detection and adjustment of the temperature of the substrate support 106 (and/or the substrate 102), the temperature of the plate 171, and/or the temperature of the reflector 127; adjustability of parameters (such as temperatures, gas flow paths, gas flow rates, and/or gas pressures) across a variety of operation conditions (such as low rotation speeds, high pressures, and/or low flow rates); broader and/or more modular ranges of adjustability; and increased deposition uniformity. Benefits of the present disclosure also include reduced chamber footprints; reduced or eliminated chamber component contamination; increased component lifespan; reduced chamber downtime; and increased throughput. Benefits of the present disclosure also include enhanced deposition repeatability.

As an example, the implementations of the present disclosure are modular and can be used across a variety of processing (e.g., deposition) operations and/or cleaning operations, including across a variety of operation parameters.

It is contemplated that one or more aspects disclosed herein may be combined. As an example, one or more aspects, features, components, operations and/or properties of the processing chamber 100, the controller 190, the one or more sensor devices 195, 196, 197, 198, 199, the sensor device 300 and/or the sensor device 350, the profiles in FIGS. 4A and 4B, the method 500, and/or the temperature data shown in FIGS. 6A and 6B may be combined. For example, the operations and/or parameters described in relation to FIGS. 1-4B and/or FIGS. 6A-6B can be combined with the operations and/or the parameters of the method 500. Moreover, it is contemplated that one or more aspects disclosed herein may include some or all of the aforementioned benefits.

While the foregoing is directed to embodiments of the present disclosure, other and further embodiments of the disclosure may be devised without departing from the basic scope thereof, and the scope thereof is determined by the claims that follow.

What is claimed is:

1. A non-transitory computer readable medium, the non-transitory computer readable medium comprising instructions to thermally adjust a chamber component, the instructions when executed cause a plurality of operations to be conducted, the plurality of operations comprising:
sensing a first temperature of the chamber component within a semiconductor processing chamber;
comparing the first temperature to a first set-point of the chamber component;
adjusting a purge gas flowrate of a purge gas supplied to a portion of the semiconductor processing chamber, the portion at least partially physically isolated from a processing portion by a thermally transmissive window;
sensing a second temperature of a reflector component in the portion of the semiconductor processing chamber;
comparing the second temperature of the reflector component to a second set-point of the reflector component; and
initiating a reflector cooling operation within the reflector component when the second temperature exceeds the second set-point.

2. The non-transitory computer readable medium of claim 1, wherein the purge gas is air.

3. The non-transitory computer readable medium of claim 1, wherein the adjusting of the purge gas flowrate is incremental using a variable speed blower.

4. The non-transitory computer readable medium of claim 3, wherein the incremental adjusting of the purge gas flowrate is by 25 percent.

5. The non-transitory computer readable medium of claim 1, further comprising heating the portion of the semiconductor processing chamber with a heater disposed therein.

6. The non-transitory computer readable medium of claim 5, wherein the heater is a ceramic heater.

7. The non-transitory computer readable medium of claim 5, wherein the heater is a silicon carbide containing heater.

8. The non-transitory computer readable medium of claim 1, further comprising adjusting a position of a substrate support by raising or lowering the substrate support.

9. The non-transitory computer readable medium of claim 1, wherein the chamber component is an isolation plate positioned to at least partially fluidly isolate the processing portion from an isolated portion above the processing portion.

10. The non-transitory computer readable medium of claim 1, wherein the sensing of the second temperature of the reflector component in the portion of the semiconductor processing chamber is performed by a sensor device disposed on a chamber lid, and the reflector component is configured to support a plurality of second sensor devices.

11. The non-transitory computer readable medium of claim 10, wherein each of the plurality of second sensor devices is configured to sense one or more wavelengths and is configured to be disposed about 200 millimeters to about 240 millimeters from a top surface of a substrate.

12. The non-transitory computer readable medium of claim 1, wherein the reflector cooling operation is a cooling flush maintaining the second temperature below 50 degrees Celsius.

13. A non-transitory computer readable medium, the non-transitory computer readable medium comprising instructions to thermally adjust an isolation plate, the instructions when executed cause a plurality of operations to be conducted, the plurality of operations comprising:
sensing a temperature of the isolation plate within a semiconductor processing chamber;
comparing the sensed temperature to a set-point of the isolation plate;
adjusting a chilled purge gas flowrate of a chilled purge gas supplied to an isolated portion of an upper volume between a thermally transmissive window and the isolation plate; and
adjusting a purge gas flowrate of a purge gas supplied to a portion of the semiconductor processing chamber at least partially physically isolated from the isolated portion by the thermally transmissive window.

14. The non-transitory computer readable medium of claim 13, wherein the sensing of the temperature of the isolation plate within the semiconductor processing chamber is performed by a plurality of sensor devices.

15. The non-transitory computer readable medium of claim 14, wherein the plurality of sensor devices are supported by a reflector component disposed within the portion of the semiconductor processing chamber.

16. The non-transitory computer readable medium of claim 14, wherein the plurality of operations further comprise disposing the plurality of sensor devices about 200 millimeters to about 240 millimeters from a top surface of a substrate.

17. A system for processing substrates and applicable for semiconductor manufacturing, the system comprising:
a chamber body comprising one or more sidewalls;
a lid;
a reflector component supported by the lid;
one or more sensor devices disposed within the reflector component;
a window, the one or more sidewalls, the window, and the lid at least partially defining an internal volume;
one or more heat sources configured to heat the internal volume;
a substrate support disposed in the internal volume;
an isolation plate disposed in the internal volume between the substrate support and the window; and
a controller comprising instructions that, when executed, cause a plurality of operations to be conducted, the plurality of operations comprising:
sensing a first temperature of the isolation plate;
comparing the first temperature to a first set-point of the isolation plate;
adjusting a purge gas flowrate of a purge gas supplied to a portion of the chamber body at least partially physically isolated from the internal volume by the window;
sensing a second temperature of the reflector component in the portion of the chamber body;
comparing the second temperature of the reflector component to a second set-point of the reflector component; and
initiating a reflector cooling operation within the reflector component when the second temperature exceeds the second set-point.

18. The system of claim 17, wherein each of the one or more sensor devices is configured to sense one or more wavelengths and is configured to be disposed about 200 millimeters to about 240 millimeters from a top surface of a substrate.

19. The system of claim 17, further comprising a heater disposed within the portion of the chamber body.

20. The system of claim 17, further comprising a variable speed blower coupled to the one or more sidewalls.
